(19) United States
(12) Patent Application Publication
(10) Pub. No.: US 2024/0056049 A1
(43) Pub. Date: Feb. 15, 2024

(54) NO-CONTACT VIA FOR HEAT DISSIPATION PATH

(71) Applicant: SKYWORKS SOLUTIONS, INC., Irvine, CA (US)

(72) Inventors: Kazuki Yamamura, Osaka-Shi (JP); Joji Fujiwara, Suita-Shi (JP)

(21) Appl. No.: 18/229,276

(22) Filed: Aug. 2, 2023

Related U.S. Application Data
(60) Provisional application No. 63/370,845, filed on Aug. 9, 2022.

(51) Int. Cl. H03H 9/08

(52) U.S. Cl. CPC H03H 9/08

(57) ABSTRACT

An electronic device comprises one or more heat generating circuit elements and a no-contact via thermally coupled to the one or more heat generating circuit elements to increase dissipation of heat from the electronic device.

### CROSS-REFERENCE TO RELATED APPLICATIONS

This application claims priority under 35 U.S.C. § 119(e) to U.S. Provisional Patent Application Ser. No. 63/370,845, titled “NO-CONTACT VIA FOR HEAT DISSIPATION PATH”, filed Aug. 9, 2022, the entire content of which is incorporated herein by reference for all purposes.

### BACKGROUND

### Technical Field

Embodiments of this disclosure relate to acoustic wave devices and to thermal management of same.

### Description of Related Technology

Acoustic wave devices, for example, surface acoustic wave (SAW) and bulk acoustic wave (BAW) devices may be utilized as components of filters in radio frequency electronic systems. For instance, filters in a radio frequency front-end of a mobile phone can include acoustic wave filters. Two acoustic wave filters can be arranged as a duplexer.

### BRIEF DESCRIPTION OF THE DRAWINGS

Embodiments of this disclosure will now be described, by way of non-limiting example, with reference to the accompanying drawings.

FIG. 1 is a simplified plan view of an example of a surface acoustic wave resonator;

FIG. 2 is a cross-sectional view of a portion of the surface acoustic wave resonator of FIG. 1;

FIG. 3 is a simplified cross-sectional view of a bulk acoustic wave resonator having a film bulk acoustic wave resonator configuration;

FIG. 4 is a simplified cross-sectional view of a bulk acoustic wave resonator having a Lamb wave resonator configuration;

FIG. 5 is a simplified cross-sectional view of a bulk acoustic wave resonator having a solidly mounted resonator configuration;

FIG. 6A is a simplified circuit diagram of an example of a ladder filter;

FIG. 6B is a simplified circuit diagram of another example of a ladder filter;

FIG. 7A is a simplified circuit diagram of a duplexer including surface acoustic wave resonators;

FIG. 7B is a simplified circuit diagram of a duplexer including bulk acoustic wave resonators;

FIG. 7C is a simplified circuit diagram of a duplexer including surface acoustic wave resonators and bulk acoustic wave resonators;

FIG. 8 illustrates an example of a via structure;

FIG. 9 illustrates an example of a no-contact via structure;

FIG. 10A illustrates an acoustic wave device die including a no-contact via structure;

FIG. 10B illustrates an acoustic wave device die including multiple no-contact via structures;

FIG. 11 is a block diagram of one example of a filter module that can include one or more surface acoustic wave resonators and no-contact via structures according to aspects of the present disclosure;

FIG. 12 is a block diagram of one example of a front-end module that can include one or more filter modules with no-contact via structures according to aspects of the present disclosure; and

FIG. 13 is a block diagram of one example of a wireless device including the front-end module of FIG. 12.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

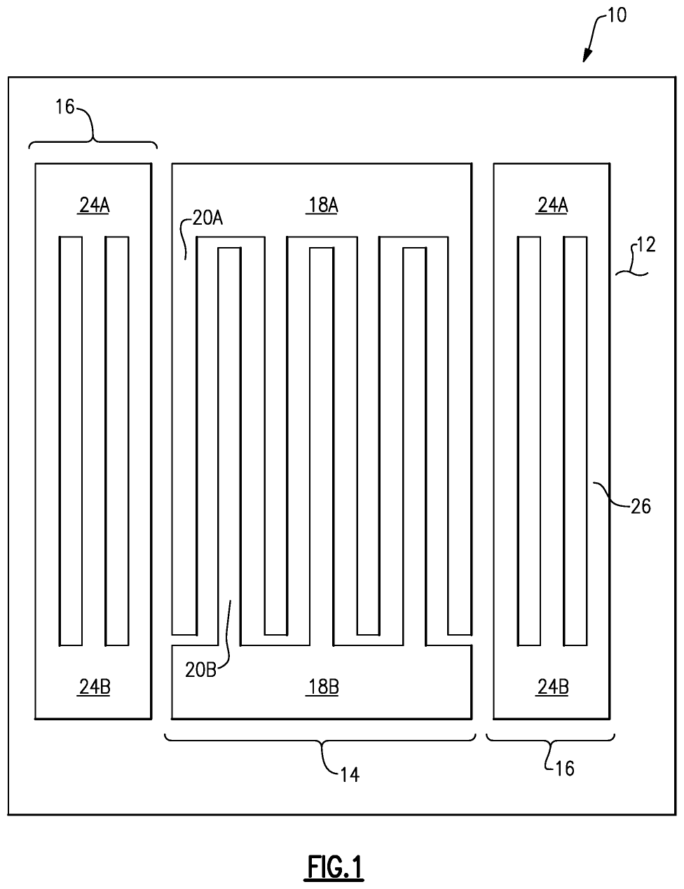

FIG. 1 is a plan view of a surface acoustic wave (SAW) resonator 10 such as might be used in a SAW filter, duplexer, balun, etc.

Surface acoustic wave resonator 10 is formed on a piezoelectric substrate, for example, a lithium tantalate (LiTaO₃) or lithium niobate (LiNbO₃) substrate 12 and includes Interdigital Transducer (IDT) electrodes 14 and reflector electrodes 16. In use, the IDT electrodes 14 excite a main acoustic wave having a wavelength λ along a surface of the piezoelectric substrate 12. The reflector electrodes 16 sandwich the IDT electrodes 14 and reflect the main acoustic wave back and forth through the IDT electrodes 14. The main acoustic wave of the device travels perpendicular to the lengthwise direction of the IDT electrodes.

The IDT electrodes 14 include a first bus bar electrode 18A and a second bus bar electrode 18B facing first bus bar electrode 18A. The IDT electrodes 14 further include first electrode fingers 20A extending from the first bus bar electrode 18A toward the second bus bar electrode 18B, and second electrode fingers 20B extending from the second bus bar electrode 18B toward the first bus bar electrode 18A.

The reflector electrodes 16 (also referred to as reflector gratings) each include a first reflector bus bar electrode 24A and a second reflector bus bar electrode 24B and reflector fingers 26 extending between and electrically coupling the first bus bar electrode 24A and the second bus bar electrode 24B.

It should be appreciated that the surface acoustic wave resonator 10 illustrated in FIG. 1, as well as the other circuit elements illustrated in other figures presented herein, is illustrated in a highly simplified form. The relative dimensions of the different features are not shown to scale. Further, typical surface acoustic wave resonators would commonly include a far greater number of electrode fingers and reflector fingers than illustrated in FIG. 1. Typical surface acoustic wave resonators or filter elements may also include multiple IDT electrodes sandwiched between the reflector electrodes.

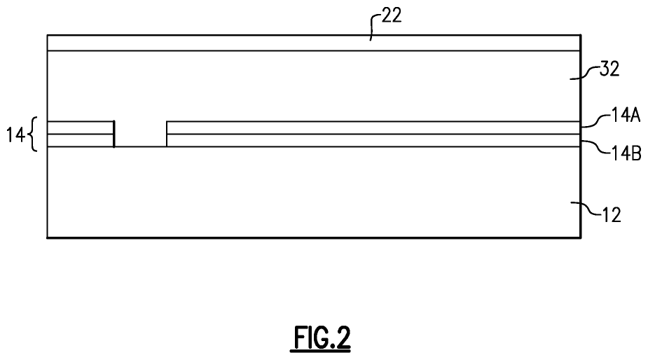

FIG. 2 is a cross-sectional view of a portion of the surface acoustic wave (SAW) resonator 10 of FIG. 1. In some embodiments a dielectric material 32, for example, silicon dioxide (SiO₂) may be disposed over the entire IDT electrode structure. In some embodiments, a layer of a dielectric 22 exhibiting a higher acoustic wave velocity than the dielectric material 32, for example, silicon nitride (Si₃N₄, also abbreviated as “SiN” herein) may be disposed over the dielectric material 32. It should be understood that the various embodiments of SAW resonators disclosed herein may each include both layers 22 and 32, or may omit one or both of these layers.

The SiO₂ layer 32 may have a negative temperature coefficient of frequency, which helps to offset the positive temperature coefficient of frequency of the piezoelectric substrate 12 and reduce the change in frequency response of the SAW device with changes in temperature. A SAW device with a layer of SiO₂ over the IDT electrodes may thus be referred to as a temperature-compensated SAW device, or TCSAW.

As also illustrated in FIG. 2, the IDT electrodes 14 may be layered electrodes including an upper layer 14A of a highly conductive but low-density material, for example, aluminum (Al), and a lower layer 14B of a less conductive, but more dense material, for example, molybdenum (Mo) or tungsten (W). The denser lower layer 14B may reduce the acoustic velocity of acoustic waves travelling through the device which may allow the IDT electrode fingers to be spaced more closely for a given operating frequency and allow the SAW device to be reduced in size as compared to a similar device utilizing less dense IDT electrodes. The less dense upper layer 14A may have a higher conductivity than the lower layer 14B to provide the electrode stack with a lower overall resistivity.

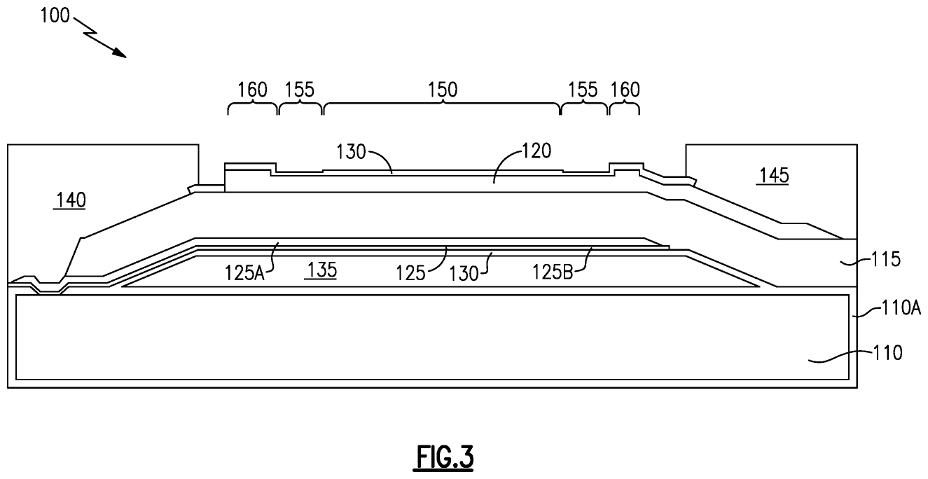

Acoustic wave resonators may also be configured as bulk acoustic wave resonators in which an induced acoustic wave travels through the bulk of the piezoelectric substrate rather than along an upper surface as in SAW resonators. FIG. 3 is cross-sectional view of an example of a bulk acoustic wave resonator having a film bulk acoustic wave resonator (FBAR) configuration, indicated generally at 100. The FBAR 100 is disposed on a substrate 110, for example, a silicon substrate that may include a dielectric surface layer 110A of, for example, silicon dioxide. The FBAR 100 includes a layer or film of piezoelectric material 115, for example, aluminum nitride (AlN). A top electrode 120 is disposed on top of a portion of the layer or film of piezoelectric material 115 and a bottom electrode 125 is disposed on the bottom of a portion of the layer or film of piezoelectric material 115. The top electrode 120 may be formed of, for example, ruthenium (Ru). The bottom electrode 125 may include a layer 125A of Ru disposed in contact with the bottom of the portion of the layer or film of piezoelectric material 115 and a layer 125B of titanium (Ti) disposed on a lower side of the layer 125A of Ru opposite a side of the layer 125A of Ru in contact with the bottom of the portion of the layer or film of piezoelectric material 115. Each of the top electrode 120 and the bottom electrode 125 may be covered with a layer of dielectric material 130, for example, silicon dioxide. A cavity 135 is defined beneath the layer of dielectric material 130 covering the bottom electrode 125 and the surface layer 110A of the substrate 110. A bottom electrical contact 140 formed of, for example, copper may make electrical connection with the bottom electrode 125 and a top electrical contact 145 formed of, for example, copper may make electrical connection with the top electrode 120.

The FBAR 100 may include a central region 150 including a main active domain in the layer or film of piezoelectric material 115 in which a main acoustic wave is excited during operation. The central region may have a width of, for example, between about 20 μm and about 100 μm. A recessed frame region or regions 155 may bound and define the lateral extent of the central region 150. The recessed frame regions may have a width of, for example, about 1 μm. The recessed frame region(s) 155 may be defined by areas that have a thinner layer of dielectric material 130 on top of the top electrode 120 than in the central region 150. The dielectric material layer 130 in the recessed frame region(s) 155 may be from about 10 nm to about 100 nm thinner than the dielectric material layer 130 in the central region 150. The difference in thickness of the dielectric material in the recessed frame region(s) 155 vs. in the central region 150 may cause the resonant frequency of the device in the recessed frame region(s) 155 to be between about 5 MHz to about 50 MHz higher than the resonant frequency of the device in the central region 150. In some embodiments, the thickness of the dielectric material layer 130 in the central region 150 may be about 200 nm to about 300 nm and the thickness of the dielectric material layer 130 in the recessed frame region(s) 155 may be about 100 nm. The dielectric film 300 in the recessed frame region(s) 155 is typically etched during manufacturing to achieve a desired difference in acoustic velocity between the central region 150 and the recessed frame region(s) 155. Accordingly, the dielectric film 300 initially deposited in both the central region 150 and recessed frame region(s) 155 is deposited with a sufficient thickness that allows for etching of sufficient dielectric film 300 in the recessed frame region(s) 155 to achieve a desired difference in thickness of the dielectric film 300 in the central region 150 and recessed frame region(s) 155 to achieve a desired acoustic velocity difference between these regions.

A raised frame region or regions 160 may be defined on an opposite side of the recessed frame region(s) 155 from the central region 150 and may directly abut the outside edge(s) of the recessed frame region(s) 155. The raised frame regions may have widths of, for example, about 1 μm. The raised frame region(s) 160 may be defined by areas where the top electrode 120 is thicker than in the central region 150 and in the recessed frame region(s) 155. The top electrode 120 may have the same thickness in the central region 150 and in the recessed frame region(s) 155 but a greater thickness in the raised frame region(s) 160. The top electrode 120 may be between about 50 nm and about 500 nm thicker in the raised frame region(s) 160 than in the central region 150 and/or in the recessed frame region(s) 155. In some embodiments the thickness of the top electrode in the central region may be between 50 and 500 nm.

The recessed frame region(s) 155 and the raised frame region(s) 160 may contribute to dissipation or scattering of transverse acoustic waves generated in the FBAR 100 during operation and/or may reflect transverse waves propagating outside of the recessed frame region(s) 155 and the raised frame region(s) 160 and prevent these transverse acoustic waves from entering the central region and inducing spurious signals in the main active domain region of the FBAR. Without being bound to a particular theory, it is believed that due to the thinner layer of dielectric material 130 on top of the top electrode 120 in the recessed frame region(s) 155, the recessed frame region(s) 155 may exhibit a higher velocity of propagation of acoustic waves than the central region 150. Conversely, due to the increased thickness and mass of the top electrode 120 in the raised frame region(s) 160, the raised frame regions(s) 160 may exhibit a lower velocity of propagation of acoustic waves than the central region 150 and a lower velocity of propagation of acoustic waves than the recessed frame region(s) 155. The discontinuity in acoustic wave velocity between the recessed frame region(s) 155 and the raised frame region(s) 160 creates a barrier that scatters, suppresses, and/or reflects transverse acoustic waves.

Another form of BAW resonator is a Lamb wave acoustic wave resonator. A Lamb wave resonator can combine features of a surface acoustic wave (SAW) resonator and a BAW resonator. A Lamb wave resonator typically includes an interdigital transducer (IDT) electrode similar to a SAW resonator. Accordingly, the frequency of the Lamb wave resonator can be lithographically defined. A Lamb wave resonator can achieve a relatively high quality factor (Q) and a relatively high phase velocity like a BAW resonator (e.g., due to a suspended structure). A Lamb wave resonator that includes an AlN piezoelectric layer can be relatively easy to integrate with other circuits, for example, because AlN process technology can be compatible with complementary metal oxide semiconductor (CMOS) process technology. AlN Lamb wave resonators can overcome a relatively low resonance frequency limitation and integration challenge associated with SAW resonators and also overcome multiple frequency capability challenges associated with BAW resonators. Some Lamb wave resonator topologies are based on acoustic reflection from periodic reflective gratings. Some other Lamb wave resonator topologies are based on acoustic reflection from suspended free edges of a piezoelectric layer.

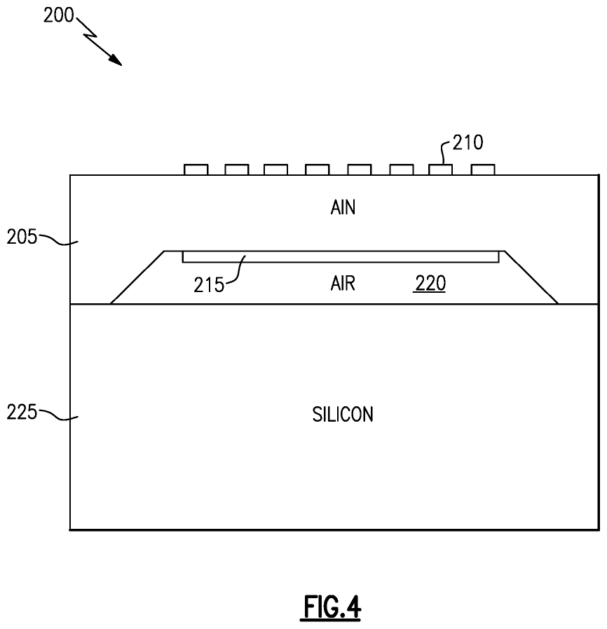

An example of a Lamb wave acoustic wave resonator is indicated generally at 200 in FIG. 4. The Lamb wave resonator 200 includes features of a SAW resonator and an FBAR. As illustrated, the Lamb wave resonator 200 includes a piezoelectric layer 205, an interdigital transducer electrode (IDT) 210 on the piezoelectric layer 205, and a lower electrode 215 disposed on a lower surface of the piezoelectric layer 205. The piezoelectric layer 205 can be a thin film. The piezoelectric layer 205 can be an aluminum nitride layer. In other instances, the piezoelectric layer 205 can be any suitable piezoelectric layer. The resonant frequency of the Lamb wave resonator can be based on the geometry of the IDT 210. The electrode 215 can be grounded in certain instances. In some other instances, the electrode 215 can be floating. An air cavity 220 is disposed between the electrode 215 and a semiconductor substrate 225. Any suitable cavity can be implemented in place of the air cavity 220, for example, a vacuum cavity or a cavity filled with a different gas.

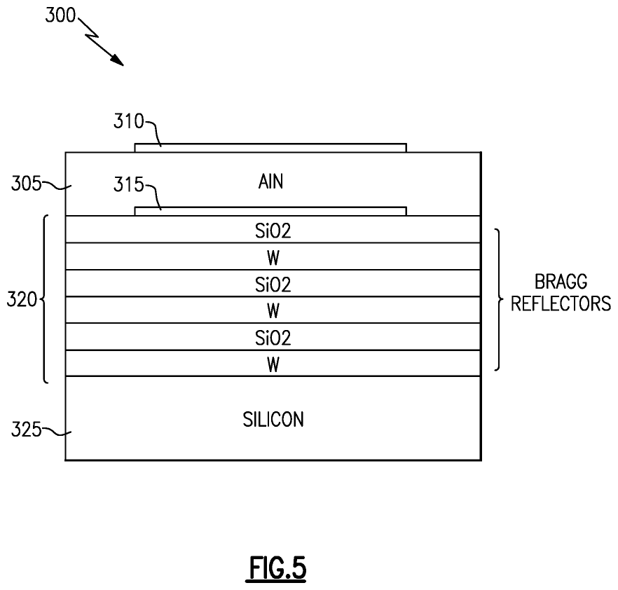

Another form of BAW resonator is a solidly mounted resonator (SMR). An example of an SMR is illustrated generally at 300 in FIG. 5. As illustrated, the SMR 300 includes a piezoelectric layer 305, an upper electrode 310 on the piezoelectric layer 305, and a lower electrode 315 on a lower surface of the piezoelectric layer 305. The piezoelectric layer 305 can be an aluminum nitride layer. In other instances, the piezoelectric layer 305 can be any other suitable piezoelectric layer. The lower electrode 315 can be grounded in certain instances. In some other instances, the lower electrode 315 can be floating. Bragg reflectors 320 are disposed between the lower electrode 315 and a semiconductor substrate 325. The semiconductor substrate 325 can be a silicon substrate. Any suitable Bragg reflectors can be implemented. For example, the Bragg reflectors can be SiO₂/W.

Examples of acoustic wave resonators as disclosed herein may be combined to form a ladder filter for a radio frequency device, for example, a cellular telephone. The acoustic wave resonators may be SAW or BAW resonators. The BAW resonators may be any of film bulk acoustic wave resonators, Lamb wave resonators, solidly mounted resonators, or any combination of these types of resonators. A ladder filter may function as a band pass filter exhibiting low attenuation for signals within a certain frequency range, referred to as the passband of the filter, while exhibiting high attenuation for signals with frequencies above and below the passband, referred to as the stop bands of the filter.

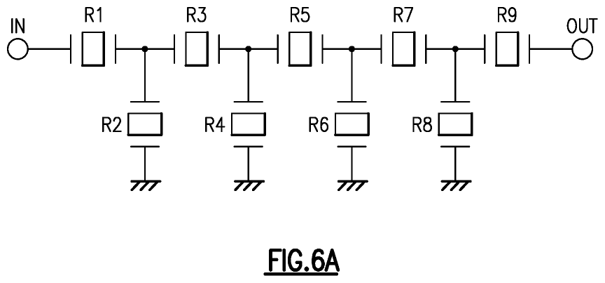

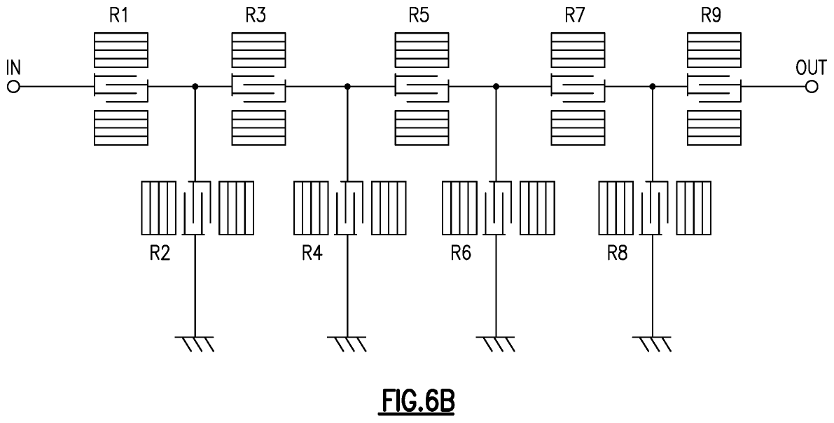

A simplified circuit diagram for one example of a ladder filter configuration is illustrated in FIG. 6A. The RF ladder filter schematically illustrated in FIG. 6A includes a plurality of series resonators R1, R3, R5, R7, and R9, and a plurality of shunt resonators R2, R4, R6, and R8. As shown, the plurality of series resonators R1, R3, R5, R7, and R9 are connected in series between the input and the output of the RF ladder filter, and the plurality of shunt resonators R2, R4, R6, and R8 are respectively connected between series resonators and ground in a shunt configuration. The RF ladder filter of FIG. 6A is illustrated as being formed from BAW resonators, however, RF ladder filters may alternatively be formed from SAW resonators, as illustrated schematically in FIG. 6B. In other embodiments, a ladder filter may include a combination of SAW and BAW resonators.

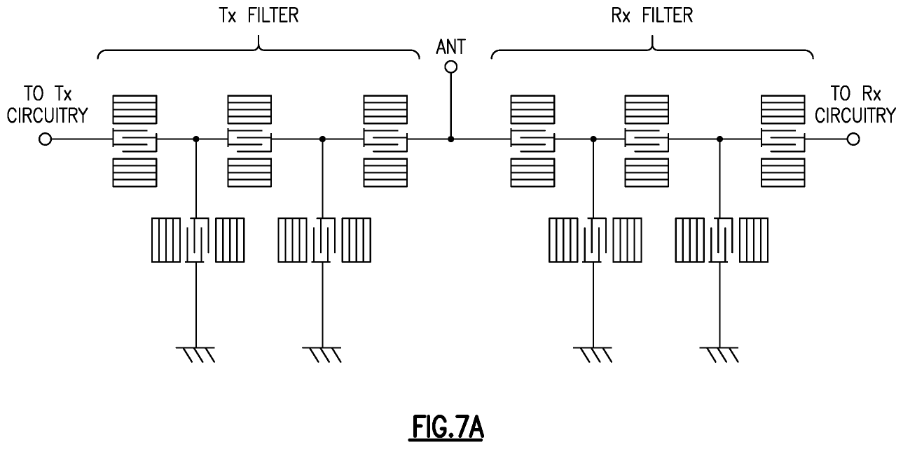

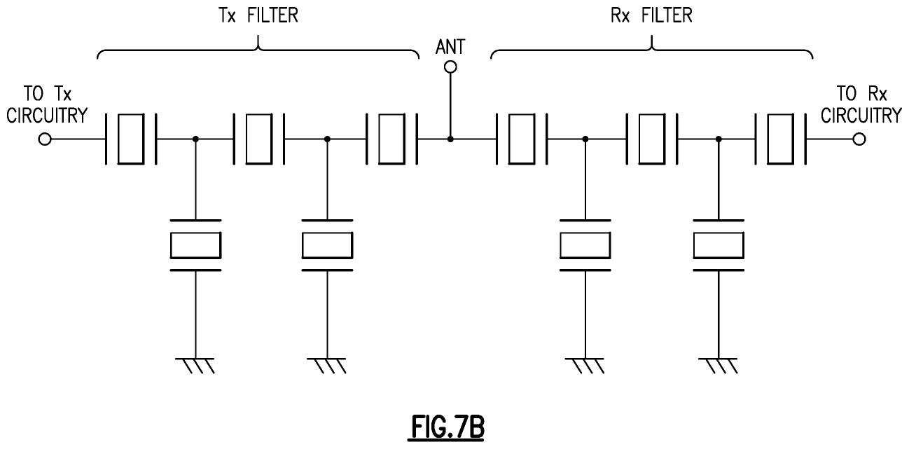

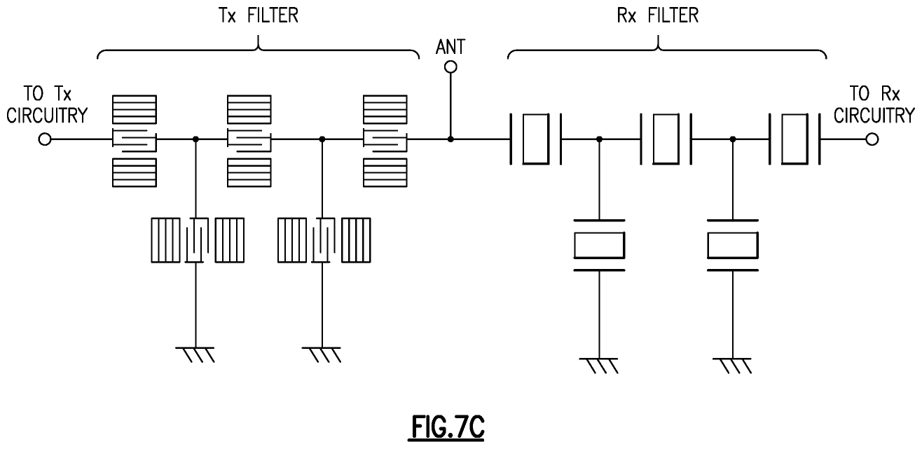

SAW or BAW resonators may also be combined to form a duplexer. A duplexer typically includes a transmit (Tx) side filter and a receive (Rx) side filter both coupled to an antenna port (Ant). The TX filter receives signals to be transmitted from transmission circuitry of a radio frequency device, filters the transmit signals, and provides the filtered transmit signals to an antenna electrically connected to the antenna port. Conversely, signals received at the antenna are provided through the antenna port to the Rx side filter that filters the received signals and provides the filtered received signals to receiver circuitry of the RF device. Example of duplexers including SAW resonators, BAW resonators, and a combination of SAW and BAW resonators are illustrated in FIGS. 7A-7C, respectively. It is to be appreciated that these are only simplified examples. Other duplexers may include additional elements, for example, inductors, capacitors, resistors, or other matching circuit elements, and SAW or BAW resonators may be placed differently in different embodiments of duplexers.

SAW or BAW resonators may further be utilized to form other forms of RF filter devices, for example, diplexers, multiplexers, baluns, etc. The schematic designs of such devices are known in the art and not illustrated herein.

Consumers and device manufactures continue to demand electronic products such as cellular telephones with smaller form factors and/or that include additional functionality. Accordingly, there is a continuing demand for smaller and smaller electronic components used in these electronic products, for example, acoustic wave resonators and filters that are incorporated in same. As RF filter devices shrink in size, it becomes more difficult to dissipate heat generated during use of the devices. It is important to remove heat from RF filter devices because as the devices heat up the performance characteristics, for example, resonant frequency of the RF filters may change. If an RF filter device heats up too much it may even fail due to melting of one or more component parts.

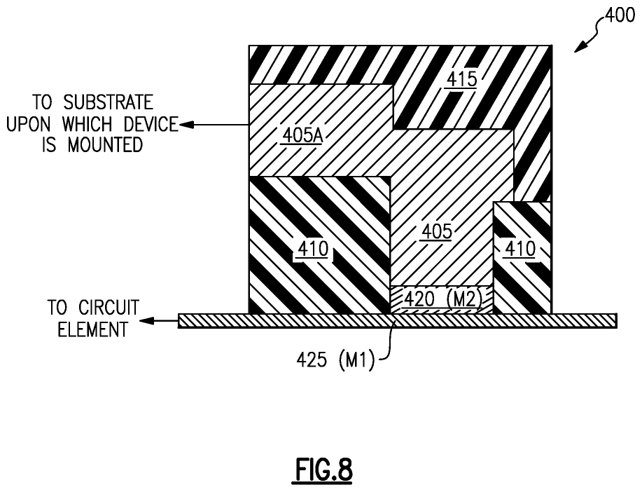

One mechanism by which heat may be removed from an RF filter device during operation is through the electrical vias that connect the circuitry of the RF filter device to a substrate upon which the RF filter device is mounted, for example, a printed circuit board. One example of a via structure 400 is illustrated in FIG. 8. The via 405 is formed of a conductive material, for example, copper. Dielectric material 410, for example, resin may at least partially define the boundaries of the via 405. A buffer coat layer 415 may be disposed above the via 405 for protection from the environment. In some manufacturing processes, the dielectric material 410 is deposited and the via 405 then formed by electroplating within a volume at least partially defined by the dielectric material 410. The bottom of the via 405 is mechanically and electrically connected to a lower conductive trace 420 which may be copper, aluminum, or any other suitable conductive material. FIG. 8 shows the bottom of the via 405 being connected to a lower conductive trace 420 formed from the M2 metal layer—the second lowest metal layer of the device including the via structure 400. FIG. 8 also shows the lower conductive trace 420 being mechanically and electrically connected to a lowest conductive trace 425, which is indicated in FIG. 8 as being the M1 metal layer—the lowest metal layer in the device. The lowest conductive trace 425 is electrically connected to a circuit element of the device, for example, to an electrode of an acoustic wave resonator. The upper end of the via 405 is mechanically and electrically coupled to an upper conductive trace 405A. The upper conductive trace 405A is electrically, mechanically, and thermally coupled to a substrate upon which a device including the via structure 400 is mounted, for example, through a solder bump or wire bond connected to a contact on the substrate. The via 405 and upper conductive trace 405A carry power or signals to and from the contact on the substrate to the circuit element through the lower conductive trace 420. Accordingly, the via 405 and conductive traces 405A, 420, 425 may provide a path for power and signals between the circuit element and the substrate. The via 405 and conductive traces 405A, 420, 425 also provide a path for heat to travel from the circuit element and out of the device into the substrate.

If one were to desire to increase the amount of heat that could be removed from a circuit element in a device to keep the circuit element from overheating, one might consider adding additional via structures similar to that of FIG. 8 to the device. The via structure 400, however, is electrically connected to the lower metal layers of the device. This may limit the places where such a via structure may be located due to limitations on how and where power or signals may be routed through the device and locations in the circuit elements of the device that are appropriate for making electrical connections to.

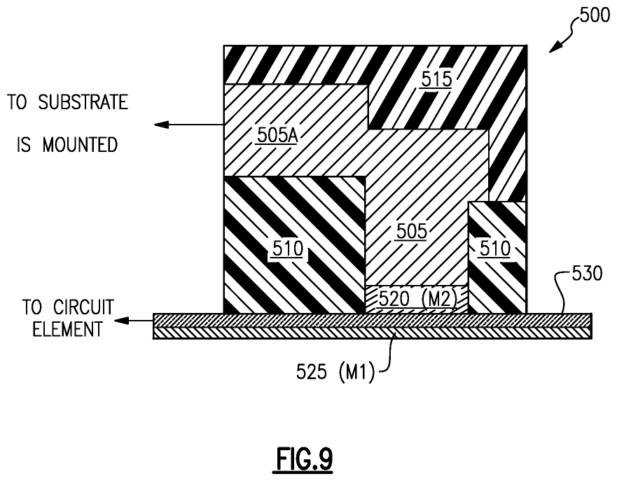

A change to the via structure 400 that may provide for more freedom for locating the structure is illustrated in FIG. 9 and indicated generally at 500. Similar elements in FIG. 9 as in FIG. 8 are indicated with similar reference numbers but with the leading 4 replaced with a 5 (5XX instead of 4XX). Via structure 500 is similar to via structure 400 with the addition of a layer of an electrically insulating material 530, for example, a dielectric such as silicon dioxide disposed between the lower conductive trace 520 to which the via 505 is mechanically and electrically connected, and the lowest conductive trace 525. The electrically insulating material 530 may be formed sufficiently thick such that current does not pass from the lowest conductive trace 525 into or from the via 505, but sufficiently thin that heat may pass through the electrically insulating material 530 from the lowest conductive trace 525 into the via 505. The via structure 500 thus provides for a thermally conductive path for removing heat from a circuit element to which the via 505 is in thermal communication with through the lowest conductive trace 525 and electrically insulating material 530 without providing an electrical path from the circuit element to the via 505. Via 505 may be referred to as a “no-contact via.” The via 505 may be electrically insulated from all circuit elements in the device in which it is included except through a circuit path external to the device, for example, from a contact pad on the substrate that the device is mounted on and that the via 505 is electrically connected to by the upper conductive trace 505A. In such instances, the via 505 may be electrically connected to the circuit element to which it is thermally coupled only through an external contact of the device.

Although referred to as conductive trace 505A, it is not necessary that trace 505A be electrically conductive. In some embodiments, trace 505A may be formed from a thermally conductive, but electrically insulating, or semi-insulating material, for example, a dielectric material such as silicon dioxide, silicon nitride, silicon oxynitride, alumina, sapphire, diamond, or another suitable dielectric material.

The electrically insulating material 530 may be silicon dioxide as noted above, but in other embodiments may be silicon nitride, silicon oxynitride, alumina, sapphire, diamond, or another suitable dielectric material. The thickness of the layer of electrically insulating material 530 may be selected based on the material of which it is formed, a desired electrical resistance, and a desired thermal conductivity for the layer of electrically insulating material 530. In some embodiments, the lower conductive trace 520 may be omitted and the lower end of the via 505 may terminate on the layer of electrically insulating material 530.

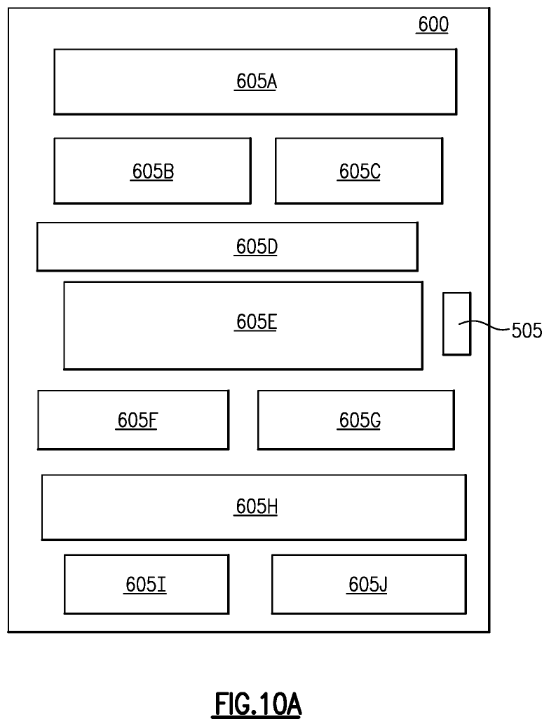

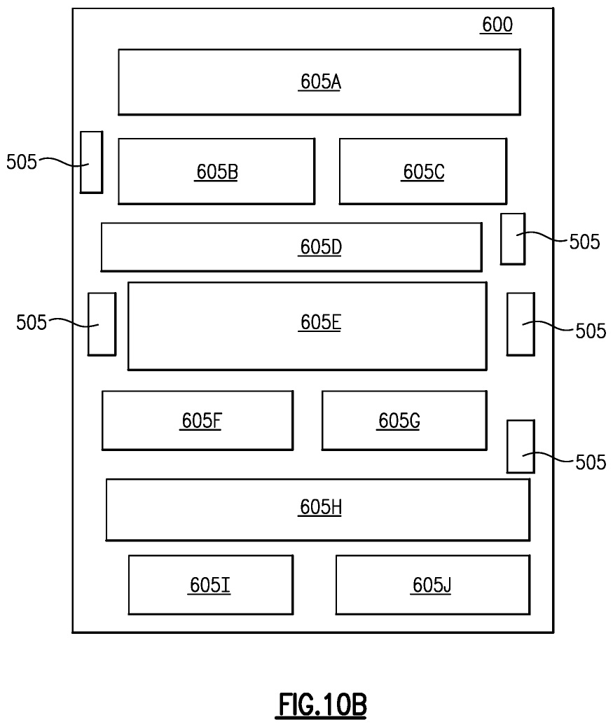

FIG. 10A is a highly schematic illustration of an electronic device, for example, an RF filter device formed on a die 600. The device may be, for example, a filter, a duplexer, a multiplexer, or any other form of acoustic wave device. The device includes circuit elements 605A-605J which may be, for example, SAW resonators or BAW resonators of any of the types described above. Electrical connections between the circuit elements and external connections are not illustrated for the sake of clarity. During operation, the device may heat up to undesirable levels. One may thus include a no-contact via 505 as described above in the device to remove heat from the device during operation and deliver the heat to an external heat sink, for example, a substrate on which the device is mounted. The no-contact via may be located proximate a circuit element that heats up the most during operation of the device, for example, circuit element 605E that is located proximate the center of the device or most central of all the circuit elements 605A-605J or to a smallest one of the series resonators in a filter. The non-contact via 505 may be in thermal communication with, but insulated from, a metal trace extending from one of the circuit elements 605A-605J and in electrical, thermal, and mechanical contact with a thermally and electrically conductive trace that is in turn electrically, thermally, and mechanically connected to an external contact of the device and to a substrate on which the device is mounted. In other embodiments, the non-contact via 505 may be in thermal, but not electrical, contact with thermally and electrically conductive traces that are in turn electrically, thermally, and mechanically connected to portions of more than one of the circuit elements 605A-605, for example, to electrodes coupled to ground in each of multiple of the circuit elements. The more than one of the circuit elements 605A-605J may be the two, three, four or more circuit elements that heat up the most during operation of the device, for example, circuit elements 605E and/or 605D and/or 605F and/or 605G most proximate the center of the device, or any of the other circuit elements.

In further embodiments, multiple no-contact vias 505 may be provided at multiple locations in the device as illustrated in FIG. 10B. The no-contact vias may be placed proximate and thermally coupled to, but electrically insulated from, one or more of the circuit elements 605A-605J that heat up most during operation of the device. For example, in a duplexer, no-contact vias may be disposed proximate transmit-side filter elements, as these may be expected to generate more heat than the receive-side filter elements during operation. Each no-contact via 505 may be thermally coupled to, but electrically insulated from, portions of one or more than one of the circuit elements 605A-605J, for example, to electrodes coupled to ground in each of multiple of the circuit elements 605A-605J.

In other embodiments, a no-contact via 505 may not necessarily be electrically, thermally, and mechanically connected to a contact on a substrate on which a device including the no-contact via 505 is mounted. Rather, the conductive trace 505A may terminate proximate to a portion of one of the external contacts of the device and be electrically insulated from the external contact or substrate by an electrically insulating material, for example, a dielectric material. Heat may flow from the portion of the one of the circuit elements 605A-605J through the dielectric material 530 into the non-contact via 505 and out of the device through the conductive trace 505A even though there is no direct electrical connection between the external contact or substrate and the non-contact via. The no-contact via 505 may be considered to be thermally connected to or thermally coupled to the external contact or substrate but not electrically connected to or coupled to external contact or substrate. The no-contact via 505 may be electrically insulated from any external connection of the electronic device including the circuit elements 605A-605J and from any substrate on which the device is mounted.

In some embodiments, the lowest conductive trace 525 need not be present directly beneath the no-contact via 505. Rather, if the electrically insulating material 530 has sufficient thermal conductivity, heat may flow from circuit elements in the device through the electrically insulating material 530 into the no-contact via 505 and through the conductive trace 505A to a heat sink external to the device, for example, a contact on a substrate on which the device is mounted.

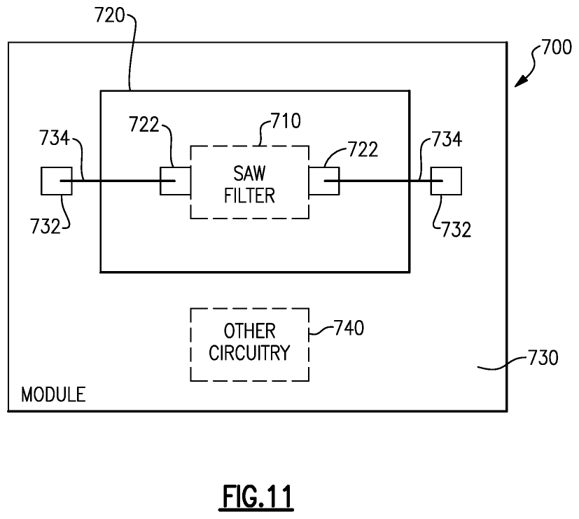

The acoustic wave devices discussed herein can be implemented in a variety of packaged modules. Some example packaged modules will now be discussed in which any suitable principles and advantages of the packaged acoustic wave devices discussed herein can be implemented. FIGS. 11, 12, and 13 are schematic block diagrams of illustrative packaged modules and devices according to certain embodiments.

As discussed above, embodiments of the surface acoustic wave elements can be configured as or used in filters, for example. In turn, a surface acoustic wave (SAW) filter using one or more surface acoustic wave elements may be incorporated into and packaged as a module that may ultimately be used in an electronic device, such as a wireless communications device, for example. FIG. 11 is a block diagram illustrating one example of a module 700 including a SAW filter 710. The SAW filter 710 may be implemented on one or more die(s) 720 including one or more connection pads 722. For example, the SAW filter 710 may include a connection pad 722 that corresponds to an input contact for the SAW filter and another connection pad 722 that corresponds to an output contact for the SAW filter. The packaged module 700 includes a packaging substrate 730 that is configured to receive a plurality of components, including the die 720. A plurality of connection pads 732 can be disposed on the packaging substrate 730, and the various connection pads 722 of the SAW filter die 720 can be connected to the connection pads 732 on the packaging substrate 730 via electrical connectors 734, which can be solder bumps or wirebonds, for example, to allow for passing of various signals to and from the SAW filter 710. The module 700 may optionally further include other circuitry die 740, for example, one or more additional filter(s), amplifiers, pre-filters, modulators, demodulators, down converters, and the like, as would be known to one of skill in the art of semiconductor fabrication in view of the disclosure herein. In some embodiments, the module 700 can also include one or more packaging structures to, for example, provide protection and facilitate easier handling of the module 700. Such a packaging structure can include an overmold formed over the packaging substrate 730 and dimensioned to substantially encapsulate the various circuits and components thereon.

Various examples and embodiments of the SAW filter 710 can be used in a wide variety of electronic devices. For example, the SAW filter 710 can be used in an antenna duplexer, which itself can be incorporated into a variety of electronic devices, such as RF front-end modules and communication devices.

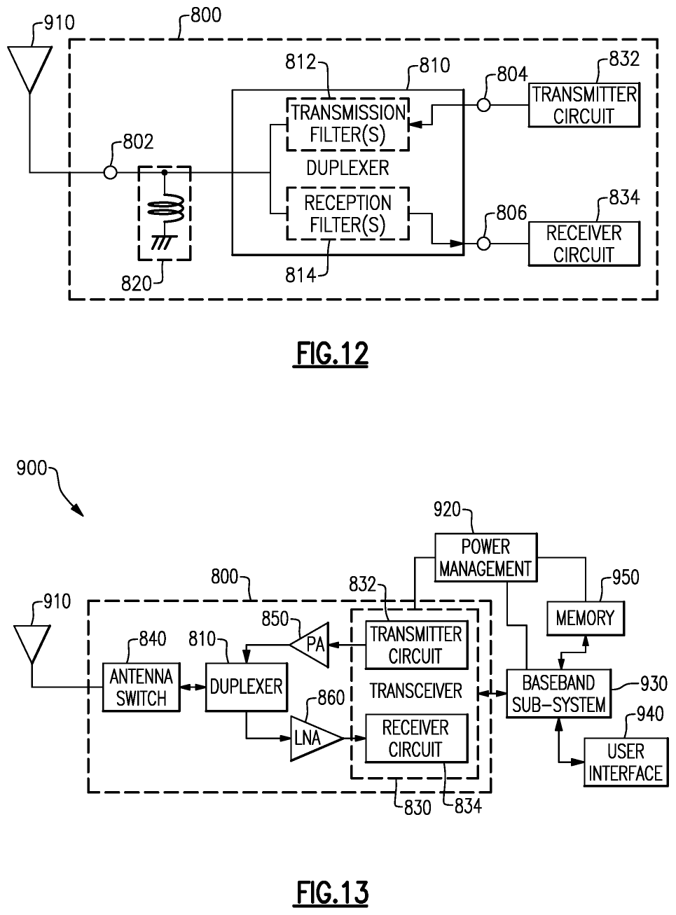

Referring to FIG. 12, there is illustrated a block diagram of one example of a front-end module 800, which may be used in an electronic device such as a wireless communications device (e.g., a mobile phone) for example. The front-end module 800 includes an antenna duplexer 810 having a common node 802, an input node 804, and an output node 806. An antenna 910 is connected to the common node 802.

The antenna duplexer 810 may include one or more transmission filters 812 connected between the input node 804 and the common node 802, and one or more reception filters 814 connected between the common node 802 and the output node 806. The passband(s) of the transmission filter(s) are different from the passband(s) of the reception filters. Examples of the SAW filter 710 can be used to form the transmission filter(s) 812 and/or the reception filter(s) 814. An inductor or other matching component 820 may be connected at the common node 802.

The front-end module 800 further includes a transmitter circuit 832 connected to the input node 804 of the duplexer 810 and a receiver circuit 834 connected to the output node 806 of the duplexer 810. The transmitter circuit 832 can generate signals for transmission via the antenna 910, and the receiver circuit 834 can receive and process signals received via the antenna 910. In some embodiments, the receiver and transmitter circuits are implemented as separate components, as shown in FIG. 12, however in other embodiments these components may be integrated into a common transceiver circuit or module. As will be appreciated by those skilled in the art, the front-end module 800 may include other components that are not illustrated in FIG. 12 including, but not limited to, switches, electromagnetic couplers, amplifiers, processors, and the like.

FIG. 13 is a block diagram of one example of a wireless device 900 including the antenna duplexer 810 shown in FIG. 12. The wireless device 900 can be a cellular phone, smart phone, tablet, modem, communication network or any other portable or non-portable device configured for voice or data communication. The wireless device 900 can receive and transmit signals from the antenna 910. The wireless device includes an embodiment of a front-end module 800 similar to that discussed above with reference to FIG. 12. The front-end module 800 includes the duplexer 810, as discussed above. In the example shown in FIG. 13 the front-end module 800 further includes an antenna switch 840, which can be configured to switch between different frequency bands or modes, such as transmit and receive modes, for example. In the example illustrated in FIG. 13, the antenna switch 840 is positioned between the duplexer 810 and the antenna 910; however, in other examples the duplexer 810 can be positioned between the antenna switch 840 and the antenna 910. In other examples the antenna switch 840 and the duplexer 810 can be integrated into a single component.

The front-end module 800 includes a transceiver 830 that is configured to generate signals for transmission or to process received signals. The transceiver 830 can include the transmitter circuit 832, which can be connected to the input node 804 of the duplexer 810, and the receiver circuit 834, which can be connected to the output node 806 of the duplexer 810, as shown in the example of FIG. 12.

Signals generated for transmission by the transmitter circuit 832 are received by a power amplifier (PA) module 850, which amplifies the generated signals from the transceiver 830. The power amplifier module 850 can include one or more power amplifiers. The power amplifier module 850 can be used to amplify a wide variety of RF or other frequency-band transmission signals. For example, the power amplifier module 850 can receive an enable signal that can be used to pulse the output of the power amplifier to aid in transmitting a wireless local area network (WLAN) signal or any other suitable pulsed signal. The power amplifier module 850 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 850 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 13, the front-end module 800 may further include a low noise amplifier module 860, which amplifies received signals from the antenna 910 and provides the amplified signals to the receiver circuit 834 of the transceiver 830.

The wireless device 900 of FIG. 13 further includes a power management sub-system 920 that is connected to the transceiver 830 and manages the power for the operation of the wireless device 900. The power management system 920 can also control the operation of a baseband sub-system 930 and various other components of the wireless device 900. The power management system 920 can include, or can be connected to, a battery (not shown) that supplies power for the various components of the wireless device 900. The power management system 920 can further include one or more processors or controllers that can control the transmission of signals, for example. In one embodiment, the baseband sub-system 930 is connected to a user interface 940 to facilitate various input and output of voice and/or data provided to and received from the user. The baseband sub-system 930 can also be connected to memory 950 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 5 GHz, such as in a range from about 600 MHz to 2.7 GHz.

### Example

Two surface acoustic wave duplexers were fabricated that were the same except for the inclusion of a no-contact via in electrical and thermal connection with a centermost surface acoustic wave resonator on one of the duplexers. A 1200 nm thick layer of silicon dioxide was used to electrically insulate the no-contact via from the M1 layer of the duplexer having the no-contact via. The duplexers were packaged and the thermal performance evaluated. With the same power input, the duplexer without the no-contact via included a hottest region that heated up to 86.3 degrees Celsius while the hottest region of the duplexer with the no-contact via heated up to 83.3 degrees Celsius. The transmit side operating power applied to the duplexer with the no-contact via was able to be increased as compared to the power applied to the duplexer without the no-contact via while still remaining within specification limits for maximum temperature. The duplexer without the no-contact via was able to operate at an output power of up to 29.43 dBm. The duplexer with the no-contact via was able to operate at an output power of up to 29.86 dBm when the proposed via is applied. When the no-contact via, the duplexer could output 0.43 dBm more power without heating up beyond specification limits.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. An electronic device comprising:
one or more heat generating circuit elements; and
a no-contact via thermally coupled to the one or more heat generating circuit elements to increase dissipation of heat from the electronic device.

2. The electronic device of claim 1 wherein the one or more heat generating circuit elements include one or more acoustic wave resonators.

3. The electronic device of claim 2 wherein the one or more acoustic wave resonators include surface acoustic wave resonators.

4. The electronic device of claim 2 wherein the one or more acoustic wave resonators include bulk acoustic wave resonators.

5. The electronic device of claim 2 wherein the one or more acoustic wave resonators form a radio frequency circuit including one or more of a ladder filter, diplexer, duplexer, or multiplexer.

6. The electronic device of claim 1 wherein the no-contact via has a lower end that terminates on a first side of a layer of an electrically insulating material and is in thermal communication with the one or more heat generating circuit elements through the layer of electrically insulating material, but not through any metal layer below the no-contact via on a second side of the layer of electrically insulating material.

7. The electronic device of claim 1 wherein the no-contact via has a lower end that terminates on a first side of a layer of electrically insulating material that electrically insulates the no-contact via from a metal layer on a second side of the layer of electrically insulating material.

8. The electronic device of claim 7 wherein the metal layer is a metal 1 layer of the electronic device.

9. The electronic device of claim 7 wherein the metal layer is in electrical and thermal communication with the one or more heat generating circuit elements.

10. The electronic device of claim 7 wherein the layer of electrically insulating material includes one of silicon dioxide, silicon nitride, silicon oxynitride, alumina, sapphire, or diamond.

11. The electronic device of claim 1 wherein the no-contact via is thermally coupled to an external contact of the electronic device by a thermally conductive trace extending from the no-contact via to the external contact.

12. The electronic device of claim 11 wherein the thermally conductive trace is electrically and thermally connected to the external contact.

13. The electronic device of claim 12 wherein the thermally conductive trace is electrically and thermally connected through the external contact to a substrate upon which the electronic device is mounted.

14. The electronic device of claim 11 wherein the no-contact via is in electrical communication with the one or more heat generating circuit elements only through the external contact.

15. The electronic device of claim 11 wherein the thermally conductive trace is thermally connected to more than one of the one or more heat generating circuit elements.

16. The electronic device of claim 11 wherein the no-contact via is thermally coupled to a one of the one or more heat generating circuit elements that generates the most heat among the one or more heat generating circuit elements during operation of the electronic device.

17. The electronic device of claim 11 wherein the thermally conductive trace is electrically insulated from the external contact to which it is thermally coupled.

18. The electronic device of claim 17 wherein the no-contact via is electrically insulated from any external connection of the electronic device.

19. The electronic device of claim 1 including multiple no-contact vias.

20. An electronics module including the electronic device of claim 1.
